(19) United States
(12) Patent Application Publication
(10) Pub. No.: US 2005/0227473 A1
(43) Pub. Date: Oct. 13, 2005

(54) Etching composition and method for etching a substrate

(75) Inventors: Yasushi Iiara, Shunan-shi (JP); Fumiharu Takahashi, Shunan-shi (JP); Hiroaki Hayashi, Hikari-shi (JP)

Correspondence Address: SUGHRUE MION, PLLC, 2100 PENNSYLVANIA AVENUE, N.W., SUITE 800, WASHINGTON, DC, 20037, US

(73) Assignees: TOSOH CORPORATION; DAINIPPON SCREEN MFG.Co.,LTD.

(21) Appl. No.: 11/081,678

(22) Filed: Mar. 17, 2005

(30) Foreign Application Priority Data
Mar. 24, 2004 (JP) 2004-087225

(51) Int. Cl. H01L 21/44

(52) U.S. Cl. 438/607

(57) ABSTRACT

This etching composition for etching hafnium compound, includes a fluoride compound and a chloride compound. This method for etching a substrate, includes etching a film which contains hafnium compound and is formed on a substrate by using an etching composition, wherein the etching composition contains a fluoride compound and a chloride compound.

### BACKGROUND OF THE INVENTION

1. Field of the Invention

The present invention relates to compositions for etching hafnium compounds such as hafnium silicate and hafnium aluminate. More specifically, the invention relates to compositions for etching dielectric films which contain hafnium silicate or hafnium aluminate and are used in semiconductor devices.

This application claims priority from Japanese Patent Application No. 2004-087225, filed on Mar. 24, 2004, the disclosure of which is incorporated herein by reference.

2. Background Art

With the rapid advances made over the past few years in information technology, there exists today a trend toward higher speed operation in large-scale integration (LSI, ULSI, VLSI) chips through smaller circuit geometries (scaling), higher packing density, and increased levels of integration. The use of new materials in semiconductor circuits is being studied for this purpose. Scaling has also led to ever thinner dielectric films, but the limits of what is possible with the silicon oxide dielectrics used until now have been reached. As a result, a different class of materials known as “high-k” materials is currently under study as new dielectric films. Potential high-k materials include aluminum oxide, zirconium oxide, and hafnium oxide, although hafnium silicate and hafnium aluminate appear to be the most promising.

To microfabricate semiconductor circuits, these hafnium oxide-based, hafnium silicate-based, or hafnium aluminate-based dielectric films, once they have been formed, must be etched. However, compounds such as hafnium oxide and hafnium silicate are not easy to etch, even with hydrofluoric acid. Therefore, it has been very difficult to etch these dielectric films at a practical rate without attacking the easily damaged semiconductor material.

One prior-art method for removing hafnium silicate is described in JP-A 2003-229401, which discloses a process that uses an aqueous solution containing hydrofluoric acid and nitric acid. But this aqueous solution does not always have sufficient etchability for hafnium silicate and hafnium aluminate, in addition to which it causes considerable damage to other semiconductor materials (particularly, silicon oxide) nearby. JP-A 2003-332297 discloses an etchant composed of hydrofluoric acid diluted with an organic solvent. However, because this etchant is largely composed of the organic solvent and thus highly flammable, its use would require that semiconductor manufacturing equipment be given an explosion-proof construction, which is industrially undesirable.

Hence, there exists a need for etchants which can thoroughly and selectively etch promising high-k materials for semiconductors, such as hafnium oxides, hafnium silicate and hafnium aluminate.

### SUMMARY OF THE INVENTION

It is thus an object of the invention to provide etching compositions which can selectively etch poorly soluble hafnium compounds, particularly hafnium silicate and hafnium aluminate, and which are non-flammable.

As a result of extensive investigations on the etching of hafnium silicate, hafnium silicate nitride, hafnium aluminate, and hafnium aluminate nitride, we have found that etching compositions containing a fluoride compound and a chloride compound are able to selectively etch hafnium compounds such as hafnium silicate and hafnium aluminate without damaging other semiconductor materials such as silicon oxide, and moreover are non-flammable.

Accordingly, the present invention provides an etching composition for etching hafnium compound, the etching composition includes a fluoride compound and a chloride compound.

By using the etching composition of the present invention, hafnium compounds can be selectively etched without damaging other semiconductor materials such as silicon oxide, and is safe to use industrially because it is non-flammable.

In the etching composition, the fluoride compound may be at least one or more selected from the group consisting of hydrofluoric acid, ammonium fluoride, and silicon fluoride.

The silicon fluoride may be silicon tetrafluoride and/or hexafluorosilicic acid.

The chloride compound may be hydrochloric acid and/or ammonium chloride.

The etching composition may further comprises phosphoric acid.

The etching composition may be for etching at least one or more hafnium compounds selected from the group consisting of hafnium silicate, hafnium silicate nitride, hafnium aluminate, and hafnium aluminate nitride.

The invention also provides a method for etching a substrate, including etching a film which contains hafnium compound and is formed on a substrate by using an etching composition, wherein the etching composition contains a fluoride compound and a chloride compound.

According to the method for etching a substrate of the present invention, hafnium compounds can be selectively etched without damaging other semiconductor materials such as silicon oxide.

In the method for etching a substrate, the fluoride compound may be at least one or more selected from the group consisting of hydrofluoric acid, ammonium fluoride, and silicon fluoride.

The silicon fluoride may be silicon tetrafluoride and/or hexafluorosilicic acid.

The chloride compound may be hydrochloric acid and/or ammonium chloride.

The etching composition may further comprises phosphoric acid.

The film may contain at least one or more hafnium compounds selected from the group consisting of hafnium silicate, hafnium silicate nitride, hafnium aluminate, and hafnium aluminate nitride.

While rotating the substrate about a vertical axis in a horizontal plane, the etching composition may be supplied to a surface of the substrate.

### BRIEF DESCRIPTION OF THE DRAWINGS

FIG. 1 is an outline front view showing a principal part of one example of components in a substrate processing unit for a single substrate process in which an etching composition of the present invention is used to etch a substrate.

FIG. 2 is a schematic view showing one example of components of an immersion-type substrate processing unit in which an etching composition of the present invention is used to etch a substrate.

### PREFERRED EMBODIMENTS

The invention is described more fully below.

This etching composition includes a fluoride compound and a chloride compound.

The fluoride compound included in the etching compositions is preferably one or more selected from the group consisting of hydrofluoric acid, ammonium fluoride and silicon fluoride. Among these fluoride compounds, ammonium fluoride and silicon fluoride are especially useful because they cause little damage to semiconductor materials.

The silicon fluoride used in the etching compositions is most preferably silicon tetrafluoride and/or hexafluorosilicic acid. When preparing the etching composition, silicon tetrafluoride is used in a form of a gas, and hexafluorosilicic acid is used in a form of a solution. The etching compositions containing these silicon fluoride can etch hafnium compounds such as hafnium silicate and hafnium aluminate without damaging other semiconductor materials, particularly silicon and silicon oxide.

For the etching compositions of the present invention, industrially available silicon tetrafluoride, or silicon tetrafluoride produced by reacting silicic acid with hydrofluoric acid may be used. The hexafluorosilicic acid may be an industrially available product or may be prepared by reacting silicon tetrafluoride with water.

The chloride compound included in the etching composition is preferably hydrochloric acid and/or ammonium chloride. Other chloride compounds may also be used, although this is not industrially desirable because they are either high-priced or contain elements which are unsuitable for the semiconductor manufacturing process.

In the etching composition, a weight ratio (wt. %) of a content of a fluoride compound to that of the overall etching composition is 0.001 to 10 wt. %, and preferably 0.01 to 5 wt. %. In the case in which the weight ratio (wt. %) of the content of the fluoride compound is less than 0.001 wt. %, a rate of etching the hafnium compound may be slower than what is required for a mass production step. In the case in which the weight ratio (wt. %) of the content of the fluoride compound is more than 10 wt. %, the etching composition is apt to damage other semiconductor materials.

In the etching composition, a weight ratio (wt. %) of a content of a chloride compound to the overall composition is 0.1 to 70 wt. %, and preferably 0.1 to 60 wt. %. In the case in which the weight ratio (wt. %) of the content of the chloride compound is less than 0.1 wt. %, no effect resulting from the chloride compound may not be obtained. In the case in which the weight ratio (wt. %) of the content of the chloride compound is more than 70 wt. %, the chloride compound may not dissolve in an aqueous solution, in addition, further improvement generally achieved in the rate of etching hafnium compound is little even the chloride compound content being more than 70 wt. %.

The etching composition may further contain phosphoric acid. Adding phosphoric acid improves the rate of etching hafnium compounds such as hafnium silicate and hafnium aluminate. The phosphoric acid is preferably one or more pyrophosphoric acids selected from the group consisting of orthophosphoric acid, metaphosphoric acid, and pyrophosphoric acid. No particular limitation is imposed on a content of the phosphoric acid, however a weight ratio (wt. %) of the content of the phosphoric acid to that of the overall etching composition is preferably in a range of about 1 to about 50 wt. %. In the case in which the ratio is less than 1%, an effect resulting from an addition of phosphoric acid is little, whereas in the case in which the ratio is more than 50 wt. %, further improvement achieved in the rate of etching hafnium compound is little.

The etching composition can be used as an aqueous solution of the fluoride compound and the chloride compound. A water content, while not subject to any particular limitation, is preferably in a range of about 10 to about 99 wt. %. In the case in which the water content is less than 10 wt. % or more than 99 wt. %, the rate of etching the hafnium compound declines.

The etching composition may also include organic compounds used for removing unwanted organic and inorganic substances during the semiconductor manufacturing process. Some examples of such organic compounds include alcohols, amides, amines, nitrites, and carboxylic acids. It is difficult to define a content of the organic compounds because a flammability differs according to the particular compound used, however, it is desirable to set this content within a range in which the etching composition does not exhibit a flash point.

A temperature at which the etching composition is used to etch hafnium compounds is 0 to 100° C., and preferably 10 to 90° C. In the case in which the temperature is less than 0° C., the rate of etching hafnium compound is so slow as to be impractical, whereas in the case in which the temperature is above 100° C., evaporation of the water makes a concentration variable, which is undesirable for industrial purposes.

The etching composition can be employed to etch hafnium compounds, particularly hafnium silicate, hafnium silicate nitride, hafnium aluminate, and hafnium aluminate nitride used as dielectric films in semiconductor devices. In the semiconductor devices, hafnium compounds are used as so-called high-k materials. The hafnium compound is deposited as a film on the semiconductor substrate by a chemical vapor deposition (CVD) method, and unnecessary areas must be removed by etching to form devices and circuits. By using the etching composition, hafnium compounds can be etched without damaging silicon oxide and other semiconductor materials.

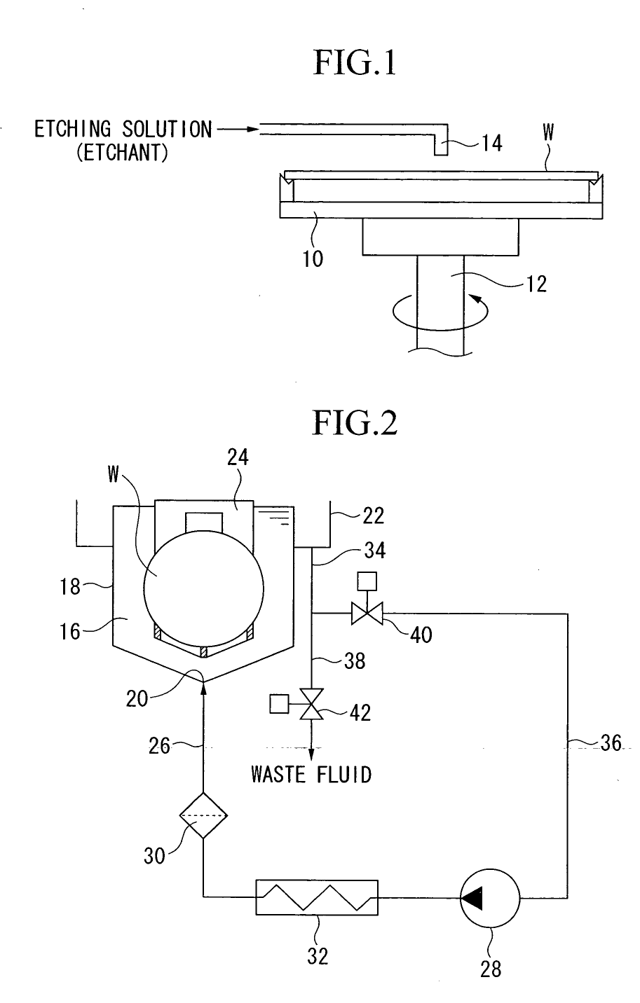

The following provides an explanation of a method for etching a substrate such as a silicon wafer using the etching composition described below with reference to FIGS. 1 and 2.

FIG. 1 is an outline front view showing a principal part of one example of components in a substrate processing unit for a single substrate process.

This substrate processing unit includes a wafer support portion 10 which holds a silicon wafer W having a film containing a hafnium compound formed on a surface thereof in a horizontal position, and a rotary spindle 12 extending downward from a central part of the wafer support portion 10 in the vertical.

The wafer support portion 10 is rotated about a rotational axis in a horizontal plane by a spin motor (not shown) connected to the rotary spindle 12. The substrate processing unit is formed so that the wafer W supported by the wafer support portion 10 rotates with the wafer support portion 10 in a unified manner. Moreover, although not shown in the figures, a cup encircling a side part and a lower part of the wafer support portion 10 is provided around the wafer support portion 10, and an etching solution scattered around or falling down from the wafer W is trapped and collected by the cup.

A nozzle 14 which supplies an etching solution to an upper surface of the wafer W is provided above the wafer W supported by the wafer support portion. The nozzle 14 is connected to an etching solution feed unit (not shown) through an etching solution feed pipe. The nozzle 14 can be made to leave the illustrated position and move toward the edge of the wafer W, and as necessary, the nozzle 14 is supported so as to move in a horizontal plane, thereby moving a discharge opening in a tip of the nozzle 14 between a center location and a periphery of the wafer W to scan the upper surface of the wafer W.

In the substrate processing unit equipped with these components, as the etching solution supplied to the nozzle 14 from the etching solution feed unit, the above-mentioned etching solution containing a fluoride compound such as hydrofluoric acid, ammonium fluoride, or silicon fluoride, and a chloride compound such as hydrochloric acid or ammonium chloride can be used. When etching the wafer W using this substrate processing unit, while rotating the wafer W about the rotational axis, the etching solution is discharged from the discharge opening in the tip of the nozzle 14 to the center location of the upper surface of the wafer W so as to disperse and spread the etching solution all over the upper surface of the wafer W. Thereby, the film including the hafnium compound formed on the wafer W is selectively etched with the etching solution containing the fluoride compound and the chloride compound. A film containing other materials such as silicon oxide formed on the wafer W is not damaged.

After etching is completed, while rotating the wafer W about the rotational axis, a cleaning fluid such as purified water is supplied to the center location of the upper surface of the wafer W so as to wash the upper surface of the wafer. At this time, as necessary, a cleaning fluid with which an ultrasonic wave is emitted to the wafer W is supplied, or a mixed fluid (spray droplet of cleaning fluid) of the cleaning fluid and an inert gas such as nitrogen is blown over to the upper surface of the wafer W using a two fluid nozzle. After washing of the wafer W, the wafer W is rotated at high speed to be dried.

FIG. 2 is a schematic view showing one example of components of an immersion-type substrate processing unit.

This substrate processing unit includes a processing tub 18 which is open at an upper part and in which an etching solution 16 is stored. An etching solution feed opening 20 is provided in a lower part of the processing tub 18. An overflow tub 22 into which the etching solution overflowed from the upper part of the processing tub 18 flows is formed in a circumference of the upper part of the processing tub 18 in a unified manner. This substrate processing unit also includes a lifter 24 which holds several silicon wafers W having the films containing the hafnium compound formed on the surfaces thereof in the processing tub 18, and several wafers W are inserted into the processing tub 18 and are discharged out of the processing tub 15, in the state they are held in by the lifter 24.

A piping 26 for etching solution supply is communicated and connected to the etching solution feed opening 20 of the processing tub 18, and the piping 26 for etching solution supply is connected to an exhaust port of a pump 28. A filter 30 and a heater 32 are provided in the piping 26 for etching solution supply. An effluence pipe 34 is connected to a bottom of the overflow tub 22, and the effluence pipe 34 branches to a piping 36 for etching solution circulation and a drain 38, and opening-and-closing control valves 40 and 42 are provided in the piping 36 for etching solution circulation and the drain 38 respectively. The piping 36 for etching solution circulation is connected to an inlet port of the pump 28.

Normally, the opening-and-closing control valve 40 is opened and the opening-and-closing control valve 42 is closed, and the etching solution discharged from the processing tub 18 through the overflow tub 22 is returned to the piping 26 for etching solution supply through the piping 36 for etching solution circulation, and through the piping 26 for etching solution supply, again supplied to the processing tub 18 and recirculated. The etching solution is heated by the heater 32 as necessary, while circulating the etching solution through the piping 26 for etching solution supply, the processing tub 18, and the piping 36 for etching solution circulation.

In the substrate processing unit equipped with these components, as the etching solution 16 supplied to the processing tub 18, the above-mentioned etching solution containing a fluoride compound such as hydrofluoric acid, ammonium fluoride, or silicon fluoride, and a chloride compound such as hydrochloric acid or ammonium chloride can be used. The film including the hafnium compound formed on the wafer W is selectively etched with the etching solution containing the fluoride compound and the chloride compound without damaging a film containing other materials such as silicon oxide by immersing several wafers W in the etching solution 16 accumulated in the processing tub 18.

Here, when etching hafnium compounds using the etching composition of the present invention, etching may be accelerated using ultrasonic waves or other suitable means.

### EXAMPLES

Examples are given below to illustrate the invention, and are not intended to limit the scope of the invention. Here, for the sake of brevity, the following symbols are used below.
SiF: silicon fluoride (which was produced by reacting silicic acid with hydrofluoric acid)
AF: ammonium fluoride
HCl: hydrochloric acid
HF: hydrofluoric acid
AC: ammonium chloride
PA: phosphoric acid (orthophosphoric acid)
IPA: 2-propanol
HfSiOₓ: hafnium silicate
HfSiONₓ: hafnium silicate nitride
SiOₓ: silicon oxide
SiN: silicon nitride

### Examples 1 to 15, Comparative Examples 1 to 3

Silicon wafer substrates on which HfSiOₓ films or HfSiONₓ films were formed with film thicknesses of 10 nm by a CVD (chemical vapor deposition) method, silicon substrates on which thermal oxide films (SiOₓ) were formed with film thicknesses of 300 nm, and silicon substrates on which SiN films were formed with film thicknesses of 100 nm were prepared. Etching compositions shown in Table 1 were also prepared, and each was added to its own polyethylene vessel. In the etchant compositions shown in Table 1, the balance of the composition was water.

TABLE 1

| | Etchant composition (wt. %) | | | | | | | |
|---|---|---|---|---|---|---|---|---|
| | Fluoride | Chloride | | Temperature | Rate of etching (nm/min) | | | |
| | compound | compound | Additive | (° C.) | HfSiOₓ | HfSiONₓ | SiOₓ | SiN |
| Example 1 | AF (0.1) | HCl (10) | | 80 | 1.096 | 1.034 | 0.120 | |
| Example 2 | AF (0.1) | HCl (10) | | 40 | 0.674 | 0.880 | 0.172 | |
| Example 3 | AF (0.1) | HCl (10) | | 25 | 0.384 | 0.514 | 0.122 | |
| Example 4 | AF (0.1) | AC (10) | PA (10) | 80 | 0.950 | 1.070 | 0.188 | |
| Example 5 | AF (0.1) | AC (10) | PA (10) | 60 | 0.606 | 0.778 | 0.000 | |
| Example 6 | AF (0.1) | AC (10) | PA (10) | 50 | 0.510 | 0.602 | 0.010 | |
| Example 7 | AF (0.1) | AC (20) | PA (10) | 50 | 0.682 | 0.912 | 0.104 | |
| Example 8 | AF (0.1) | AC (30) | PA (10) | 50 | 0.772 | 1.278 | 0.136 | |
| Example 9 | AF (0.1) | AC (10) | PA (10) | 25 | 0.418 | 0.498 | 0.160 | |
| Example 10 | AF (0.1) | HCl (10) | PA (10) | 80 | 0.950 | 1.280 | 0.018 | |
| Example 11 | AF (0.1) | HCl (10) | PA (5) | 80 | 0.360 | 0.692 | 0.000 | |
| Example 12 | SiF (1) | AC (10) | PA (10) | 80 | 0.233 | 0.462 | 0.004 | |
| Example 13 | SiF (1.5) | AC (10) | PA (10) | 80 | 0.377 | 0.521 | 0.004 | |
| Example 14 | HF (0.06) | HCl (10) | PA (10) | 50 | 0.684 | 0.780 | 0.060 | 0.096 |
| Example 15 | AF (0.1) | AC (10) | PA (10) | 50 | 0.602 | 0.670 | 0.058 | 0.122 |
| Comparative Example 1 | AF (0.1) | | PA (10) | 50 | 0.260 | 0.370 | 0.002 | |
| Comparative Example 2 | HF (1.5) | | IPA (97) | 80 | 0.826 | 1.276 | 0.898 | |
| Comparative Example 3 | HF (0.1) | | | 50 | 0.396 | 0.516 | 0.200 | 0.478 |

The prepared silicon wafer substrates and silicon substrates were immersed in the etching compositions (immersed for 10 minutes), then washed with water and dried. Thicknesses of the HfSiOₓ, HfSiONₓ, SiOₓ, and SiN films before and after immersion were measured with an optical film thickness measuring apparatus, based upon which rates of etching was determined.

The flash points of the etchants in Examples 1 to 15 and the etchants in Comparative Examples 1 and 2 were measured. The etchants in Examples 1 to 15 and Comparative Example 1 did not have flash points, but the etchant in Comparative Example 2 had a flash point of 12° C.

1. An etching composition for etching hafnium compound, the etching composition comprising a fluoride compound and a chloride compound.

2. The etching composition according to claim 1, wherein the fluoride compound is at least one or more selected from the group consisting of hydrofluoric acid, ammonium fluoride, and silicon fluoride.

3. The etching composition according to claim 2, wherein the silicon fluoride is silicon tetrafluoride and/or hexafluorosilicic acid.

4. The etching composition according to claim 1, wherein the chloride compound is hydrochloric acid and/or ammonium chloride.

5. The etching composition according to claim 1, wherein the etching composition further comprises phosphoric acid.

6. The etching composition according to claim 1 wherein the etching composition is for etching at least one or more hafnium compounds selected from the group consisting of hafnium silicate, hafnium silicate nitride, hafnium aluminate, and hafnium aluminate nitride.

7. A method for etching a substrate, comprising etching a film which contains hafnium compound and is formed on a substrate by using an etching composition,
wherein the etching composition comprises a fluoride compound and a chloride compound.

8. The method for etching a substrate according to claim 7, wherein the fluoride compound is at least one or more selected from the group consisting of hydrofluoric acid, ammonium fluoride, and silicon fluoride.

9. The method for etching a substrate according to claim 8, wherein the silicon fluoride is silicon tetrafluoride and/or hexafluorosilicic acid.

10. The method for etching a substrate according to claim 7, wherein the chloride compound is hydrochloric acid and/or ammonium chloride.

11. The method for etching a substrate according to claim 7, wherein the etching composition further comprises phosphoric acid.

12. The method for etching a substrate according to claim 7, wherein the film contains at least one or more hafnium compounds selected from the group consisting of hafnium silicate, hafnium silicate nitride, hafnium aluminate, and hafnium aluminate nitride.

13. The method for etching a substrate according to claim 7, wherein while rotating the substrate about a vertical axis in a horizontal plane, supplying the etching composition to a surface of the substrate.

14. The etching composition according to claim 2, wherein the etching composition further comprises phosphoric acid.

15. The etching composition according to claim 3, wherein the etching composition further comprises phosphoric acid.

16. The etching composition according to claim 4, wherein the etching composition further comprises phosphoric acid.

17. The method for etching a substrate according to claim 8, wherein the etching composition further comprises phosphoric acid.

18. The method for etching a substrate according to claim 9, wherein the etching composition further comprises phosphoric acid.

19. The method for etching a substrate according to claim 10, wherein the etching composition further comprises phosphoric acid.
